(19) United States
(12) Patent Application Publication
(10) Pub. No.: US 2024/0413096 A1
(43) Pub. Date: Dec. 12, 2024

(54) SEMICONDUCTOR PACKAGE COMPRISING STIFFENER STRUCTURE

(71) Applicant: Samsung Electronics Co., Ltd., Suwon-si (KR)

(72) Inventors: OKGYEONG PARK, Suwon-si (KR); MYUNGSAM KANG, Suwon-si (KR); CHIL WOO KWON, Suwon-si (KR); HYEJIN KIM, Suwon-si (KR)

(21) Appl. No.: 18/411,329

(22) Filed: Jan. 12, 2024

(30) Foreign Application Priority Data
Jun. 12, 2023 (KR) 10-2023-0075005

(51) Int. Cl. H01L 23/00; H01L 23/31; H01L 25/065; H10B 80/00

(52) U.S. Cl. CPC H01L 23/562; H01L 23/3128; H01L 25/0655; H10B 80/00; H01L 24/16; H01L 24/32; H01L 24/73; H01L 2224/16227; H01L 2224/32225; H01L 2224/73204

(57) ABSTRACT

A semiconductor package including a package substrate, a chip structure on the package substrate, a peripheral structure disposed on the package substrate and disposed around the chip structure, and a stiffener structure disposed at an edge of the package substrate and surrounding the peripheral structure and the chip structure. The stiffener structure includes a first stiffener and a second stiffener that are sequentially stacked, the second stiffener includes a material different from a material of the first stiffener, and the second stiffener has a second width wider than a first width of the first stiffener and vertically overlaps the peripheral structure.

### CROSS-REFERENCE TO RELATED APPLICATIONS

This U.S. non-provisional patent application claims priority under 35 U.S.C. § 119 to Korean Patent Application No. 10-2023-0075005, filed on Jun. 12, 2023, in the Korean Intellectual Property Office, the entire content of which is hereby incorporated by reference.

### BACKGROUND OF THE INVENTION

The present disclosure relates to a semiconductor package, and more particularly, to a semiconductor package including a stiffener structure.

Integrated circuit chips are typically provided with a semiconductor package so as to be suitably applied to circuit boards of electronic products or otherwise combined within an electronic system. In a general semiconductor package, an integrated circuit chip (or a semiconductor chip) may be mounted on a printed circuit board (PCB) and may be electrically connected to the PCB through bonding wires or bumps. Various researches for improving reliability and durability of semiconductor packages have been conducted with the development of the electronic industry.

### SUMMARY

An object of the present disclosure is to provide a semiconductor package with improved reliability.

The problem to be solved by the present disclosure is not limited to the problems mentioned above, and other problems not mentioned will be clearly understood by those skilled in the art from the following description.

A semiconductor package according to some embodiments of the present disclosure includes a package substrate, a chip structure on the package substrate, a peripheral structure disposed on the package substrate and disposed around the chip structure, and a stiffener structure disposed at an edge of the package substrate and surrounding the peripheral structure and the chip structure, wherein the stiffener structure includes a first stiffener and a second stiffener that are sequentially stacked, the second stiffener includes a material different from a material of the first stiffener, and the second stiffener has a second width wider than a first width of the first stiffener and vertically overlaps the peripheral structure.

A semiconductor package according to some embodiments of the present disclosure includes a package substrate, an interposer substrate on the package substrate, an application-specific semiconductor chip disposed on a center of the interposer substrate, first and second memory chips disposed on one side of the application-specific semiconductor chip, third and fourth memory chips disposed on the other side of the application-specific semiconductor chip, a mold layer covering the application-specific semiconductor chip, the first to fourth memory chips, and the interposer substrate, and a stiffener structure disposed at an edge of the interposer substrate and surrounding the interposer substrate, wherein the stiffener structure includes a first stiffener and a second stiffener that are sequentially stacked, the second stiffener includes a material different from a material of the first stiffener, the second stiffener has a second width wider than a first width of the first stiffener, a coefficient of thermal expansion of the first stiffener is smaller than a coefficient of thermal expansion of the second stiffener.

A semiconductor package according to some embodiments of the present disclosure includes a package substrate, a chip structure on the package substrate, and a stiffener structure disposed at an edge of the package substrate and surrounding the chip structure, wherein the stiffener structure includes a first stiffener and a second stiffener formed of different materials, and the first stiffener and the second stiffener surround the chip structure when viewed in a plan view, and the second stiffener is adjacent to an inner wall of the first stiffener.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a plan view of a semiconductor package according to embodiments of the present disclosure.

FIG. 2 is a cross-sectional view of FIG. 1 taken along line A-A′ according to embodiments of the present disclosure.

FIG. 3 is an enlarged view of portion ‘P1’ of FIG. 2 according to an embodiment of the present disclosure.

FIG. 4 is a cross-sectional view of FIG. 1 taken along line A-A′ according to embodiments of the present disclosure.

FIG. 5 is a cross-sectional view of a semiconductor package according to embodiments of the present disclosure.

FIG. 6 is a cross-sectional view of a semiconductor package according to embodiments of the present disclosure.

FIG. 7 is a cross-sectional view of a semiconductor package according to embodiments of the present disclosure.

FIG. 8 is a cross-sectional view of a semiconductor package according to embodiments of the present disclosure.

FIG. 9 is a plan view of a semiconductor package according to embodiments of the present disclosure.

FIG. 10 is a cross-sectional view of FIG. 9 taken along line A-A′ according to embodiments of the present disclosure.

FIG. 11 is a cross-sectional view of a semiconductor package according to embodiments of the present disclosure.

FIG. 12 is a plan view of a semiconductor package according to embodiments of the present disclosure.

FIG. 13 is a cross-sectional view of FIG. 12 taken along line A-A′ according to embodiments of the present disclosure.

FIG. 14 is a cross-sectional view of FIG. 12 taken along line A-A′ according to embodiments of the present disclosure.

FIG. 15 is a cross-sectional view of FIG. 12 taken along line A-A′ according to embodiments of the present disclosure.

FIG. 16A is a cross-sectional view of a semiconductor package according to embodiments of the present disclosure.

FIG. 16B is a cross-sectional view of a semiconductor package according to embodiments of the present disclosure.

FIG. 17 is a cross-sectional view of a semiconductor package according to embodiments of the present disclosure.

FIG. 18 is a cross-sectional view of a semiconductor package according to embodiments of the present disclosure.

FIG. 19 is a cross-sectional view of a semiconductor package according to embodiments of the present disclosure.

FIG. 20 is a cross-sectional view of a semiconductor package according to embodiments of the present disclosure.

FIG. 21 is a cross-sectional view of a semiconductor package according to embodiments of the present disclosure.

FIG. 22 is a cross-sectional view of a semiconductor package according to embodiments of the present disclosure.

FIG. 23 is a plan view of a semiconductor package according to embodiments of the present disclosure.

FIG. 24 is a plan view of a semiconductor package according to embodiments of the present disclosure.

FIG. 25 is a plan view of a semiconductor package according to embodiments of the present disclosure.

### DETAILED DESCRIPTION

Hereinafter, to explain the present disclosure in detail, embodiments according to the present disclosure will be described with reference to the accompanying drawings.

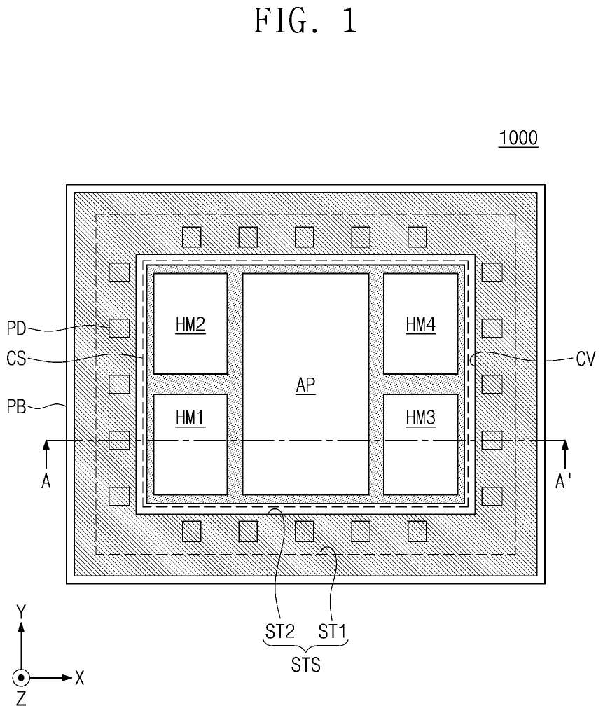

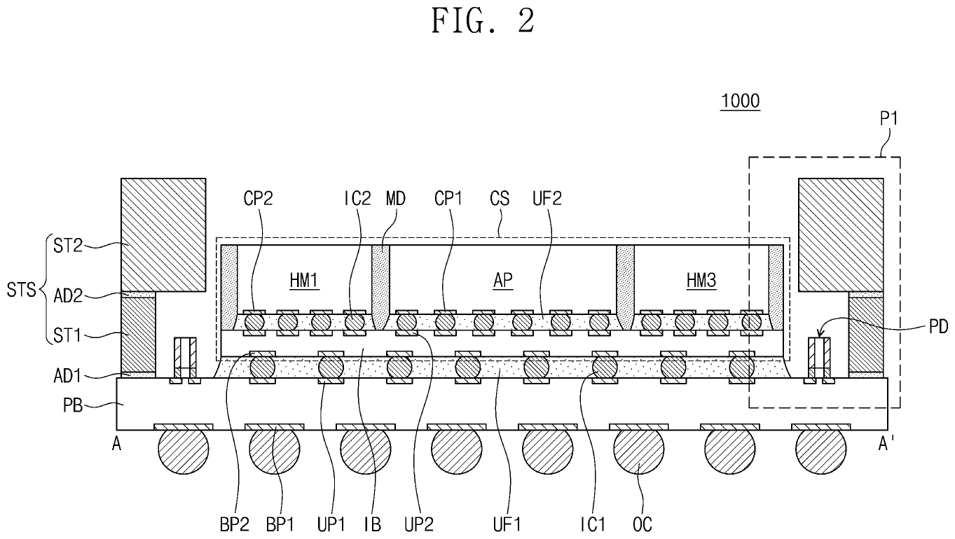

FIG. 1 is a plan view of a semiconductor package according to embodiments of the present disclosure. FIG. 2 is a cross-sectional view of FIG. 1 taken along line A-A′ according to embodiments of the present disclosure.

Referring to FIGS. 1 and 2, a semiconductor package 1000 according to embodiments may include a first substrate PB. The first substrate PB may also be referred to as a ‘package substrate’. The first substrate PB may be, for example, a double-sided or multi-layered printed circuit board. The first substrate PB may be referred to as a package substrate. The first substrate PB may include a first body layer, first substrate upper conductive patterns UP1 disposed on an upper surface thereof, and first substrate lower conductive patterns BP1 disposed on a lower surface thereof. A thermosetting resin such as epoxy resin, a thermoplastic resin such as polyimide, or a resin impregnated with a reinforcing material such as glass fiber and/or inorganic filler (e.g., prepreg), and/or a photocurable resin or the like may be used as the first body layer, but is not particularly limited thereto. The first substrate upper conductive patterns UP1 and the first substrate lower conductive patterns BP1 may include at least one of copper, aluminum, and gold. Vias may be disposed in the first body layer, and may electrically connect the first substrate upper conductive patterns UP1 to the first substrate lower conductive patterns BP1. Upper and lower surfaces of the first body layer may be covered with an insulating layer. The insulating layer may be photo-solder resist (PSR).

External connection terminals OC may be attached to the first substrate lower conductive patterns BP1 under the first substrate PB. The external connection terminals OC may be solder balls. The external connection terminals OC may include or may be formed of at least one of tin and lead.

A chip structure CS and first peripheral structures PD are disposed on the first substrate PB. The chip structure CS may be at least one selected from a system large scale integration (LSI) chip, a logic circuit chip, an image sensor chip such as a CMOS imaging sensor (CIS), a memory element chip such as a flash memory chip, a DRAM chip, an SRAM chip, an EEPROM chip, a PRAM chip, an MRAM chip, an ReRAM chip, a high bandwidth memory (HBM) chip, a hybrid memory cubic (HMC) chip, and a microelectromechanical system (MEMS) element chip, or an application-specific integrated circuit (ASIC) chip. In the present example, one chip structure CS is provided, but a plurality or more may be provided.

In detail, in the present embodiment, the chip structure CS includes a second substrate IB. That is, the second substrate IB may be mounted on the first substrate PB. The second substrate IB may also be referred to as an ‘interposer substrate’. The second substrate IB may include a second body layer, second substrate upper conductive patterns UP2 disposed on an upper surface thereof, and second substrate lower conductive patterns BP2 disposed on a lower surface thereof. Interlayer insulating layers and wirings may be disposed on a lower surface and/or an upper surface of the second body layer. The second body layer may include or may be formed of, for example, silicon. Through-vias may be disposed in the second body layer. The second substrate upper conductive patterns UP2 and the second substrate lower conductive patterns BP2 may include or may be formed of at least one of copper, aluminum, and gold. The second substrate upper conductive patterns UP2 may be electrically connected to the second substrate lower conductive patterns BP2.

The first substrate PB and the second substrate IB may be electrically connected to each other through first internal connection terminals IC1. The first internal connection terminals IC1 may electrically connect the first substrate upper conductive patterns UP1 and the second substrate lower conductive patterns BP2. The first internal connection terminals IC1 may be at least one of a solder ball, a conductive bump, and a conductive pillar. The first internal connection terminals IC1 may include or may be formed of at least one of copper, tin, and lead. A first underfill layer UF1 may be interposed between the first substrate PB and the second substrate IB.

The chip structure CS may include a central semiconductor chip AP and first to fourth peripheral semiconductor chips HM1 to HM4 mounted on the second substrate IB. The central semiconductor chip AP may be, for example, a logic chip, a processor chip, or an application-specific integrated circuit (ASIC) chip. The first and second peripheral semiconductor chips HM1 and HM2 may be adjacent to one side of the central semiconductor chip AP and may be spaced apart from each other in a second direction Y. The third and fourth peripheral semiconductor chips HM3 and HM4 are adjacent to the other side of the central semiconductor chip AP and may be spaced apart from each other in the second direction Y. Each of the first to fourth peripheral semiconductor chips HM1 to HM4 may be a memory chip or a high bandwidth memory (HBM) chip. Wirings may be disposed on the second substrate IB to electrically connect the central semiconductor chip AP and the first to fourth peripheral semiconductor chips HM1 to HM4. As a result, the central semiconductor chip AP and the first to fourth peripheral semiconductor chips HM1 to HM4 may be connected through the second substrate IB without passing through the first substrate PB, and an electrical connection length between the central semiconductor chip AP and the first to fourth peripheral semiconductor chips HM1 to HM4 may be short, and thus a signal transmission speed may be improved, thereby improving an operation speed of the semiconductor package 1000.

First chip conductive pads CP1 may be disposed on a lower surface of the central semiconductor chip AP. The first chip conductive pads CP1 may include or may be formed of metal such as aluminum or copper. Second chip conductive pads CP2 may be disposed on lower surfaces of the first to fourth peripheral semiconductor chips HM1 to HM4. The first chip conductive pads CP1 and the second chip conductive pads CP2 may be electrically connected to portions of the second substrate upper conductive patterns UP2 through second internal connection terminals IC2. The second internal connection terminals IC2 may be at least one of a solder ball, a conductive bump, and a conductive pillar. The second internal connection terminals IC2 may include or may be formed of at least one of copper, tin, and lead.

The chip structure CS may further include a second underfill layer UF2 and a mold layer MD. The second underfill layer UF2 may be interposed between the central semiconductor chip AP and the second substrate IB and between the first to fourth peripheral semiconductor chips HM1 to HM4 and the second substrate IB. The first underfill layer UF1 and the second underfill layer UF2 may include or may be formed of a thermosetting resin or a photocurable resin. Also, the first underfill layer UF1 and the second underfill layer UF2 may further include an organic filler or an inorganic filler. The mold layer MD may cover the central semiconductor chip AP and sidewalls of the first to fourth peripheral semiconductor chips HM1 to HM4 and the upper surface of the second substrate IB. An upper surface of the mold layer MD may be coplanar with upper surfaces of the central semiconductor chip AP and the first to fourth peripheral semiconductor chips HM1 to HM4. The mold layer MD may include or may be formed of, for example, an insulating resin such as an epoxy-based molding compound (EMC). The mold layer MD may further include a filler, and the filler may be dispersed in the insulating resin. The filler may include or may be formed of, for example, silicon oxide (SiO₂). A side surface of the mold layer MD may be coplanar with a side surface of the second substrate IB. Terms such as “same,” “equal,” “planar,” or “coplanar,” as used herein encompass identicality or near identicality including variations that may occur, for example, due to manufacturing processes. The term “substantially” may be used herein to emphasize this meaning, unless the context or other statements indicate otherwise.

The first peripheral structures PD may be spaced apart from each other. The first peripheral structures PD may be passive elements such as capacitors or resistors. The first peripheral structures PD are provided in the plural and may be arranged in a row to surround the chip structure CS. Levels of upper surfaces of the first peripheral structures PD are lower than levels of the upper surfaces of the chip structures CS.

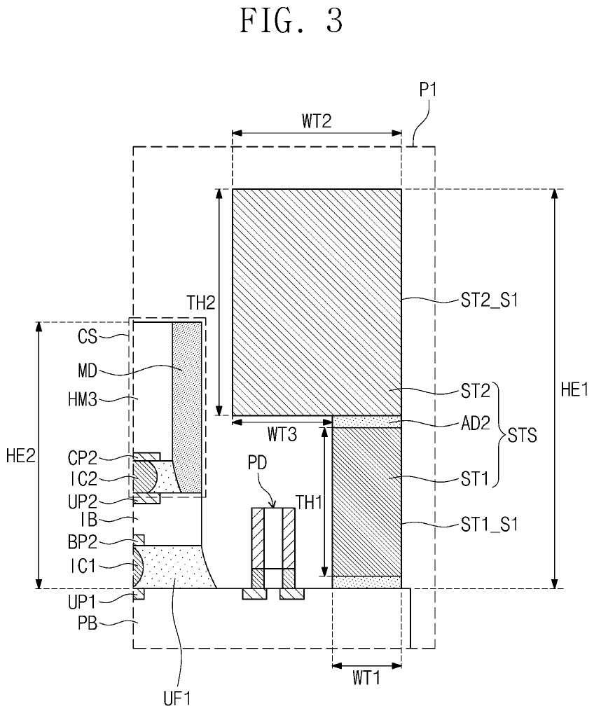

FIG. 3 is an enlarged view of portion ‘P1’ of FIG. 2 according to an embodiment of the present disclosure.

Referring to FIGS. 1 to 3, a stiffener structure STS is disposed on an edge of the first substrate PB. The stiffener structure STS may surround the chip structure CS and the first peripheral structures PD. The stiffener structure STS may have a closed curve shape having a cavity CV, which is an empty space in which the chip structure CS and the first peripheral structures PD are inserted, when viewed in a plan view. The stiffener structure STS may be attached to the upper surface of the first substrate PB by a first adhesive layer AD1. The stiffener structure STS includes a first stiffener ST1 and a second stiffener ST2 that are sequentially stacked. The first stiffener ST1 and the second stiffener ST2 may surround the chip structure CS and the first peripheral structures PD, respectively. Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

The first stiffener ST1 and the second stiffener ST2 include different materials. At least one of the first and second stiffeners ST1 and ST2 may include or may be formed of a metal such as Cu, SUS, Ti, or Al, a ceramic such as silica, titania, or alumina, SiN, or a polymer layer. The first stiffener ST1 and the second stiffener ST2 have different thermal expansion coefficients. For example, a first coefficient of thermal expansion of the first stiffener ST1 is smaller than a second coefficient of thermal expansion of the second stiffener ST2. The first coefficient of thermal expansion of the first stiffener ST1 is similar to/identical to that of the first substrate PB. The first coefficient of thermal expansion of the first stiffener ST1 may be about 9 ppm/° C. to about 13 ppm/° C. The second coefficient of thermal expansion of the second stiffener ST2 may be about 14 ppm/° C. to about 25 ppm/° C. The first stiffener ST1 may include or may be formed of, for example, at least one of stainless use steel (SUS), platinum, MgO, iron, cobalt, and nickel, and the second stiffener ST2 may be formed of, for example, of at least one of gold, copper, silicon, and aluminum. As described above, the stiffener structure STS of the present disclosure may include a plurality of stiffeners ST1 and ST2 having different thermal expansion coefficients, and thus warpage of the semiconductor package 1000 may be more effectively suppressed and controlled.

The stiffener structure STS further includes a second adhesive layer AD2 interposed between the first and second stiffeners ST1 and ST2. That is, the second stiffener ST2 may be attached to the first stiffener ST1 by the second adhesive layer AD2. The second adhesive layer AD2 may serve to alleviate physical stress.

One outer wall ST1_S1 of the first stiffener ST1 may be aligned with one outer wall ST2_S1 of the second stiffener ST2. One end surface of the first stiffener ST1 may have a first width WT1 and a first thickness TH1. One end surface of the second stiffener ST2 may have a second width WT2 and a second thickness TH2. The first thickness TH1 is different from the second thickness TH2. For example, the first thickness TH1 is greater than a height of the upper surface of the first peripheral structure PD. The second width WT2 is different from the first width WT1. In the present example, the second width WT2 is greater than the first width WT1. A portion of the second stiffener ST2 may protrude to a side of the first stiffener ST1 and may vertically overlap the first peripheral structure PD. A width WT3 of the second stiffener ST2 protruding to the side of the first stiffener ST1 may be, for example, 1 mm to 19 mm.

The structure of the stiffener structure STS of the present disclosure, when the chip structure CS and the first peripheral structure PD are mounted, may maximize a bonding area with the first substrate PB and may be effective in suppressing warpage.

The upper surface of the stiffener structure STS has a first height HE1 from the upper surface of the first substrate PB. The upper surface of the chip structure CS has a second height HE2 from the upper surface of the first substrate PB. The first height HE1 may be higher (i.e., greater) than the second height HE2. For example, the first height HE1 may be 1.1 to 3 times the second height HE2.

In another example, the semiconductor package 1000 having the structure of FIGS. 1 to 3 may exclude the first peripheral structure PD. In this case, as there is no first peripheral structure PD, a portion of the second stiffener ST2 may not overlap the first peripheral structure PD. In another example, in the semiconductor package 1000 having the structure of FIGS. 1 to 3, even when the first peripheral structure PD exists, a portion of the second stiffener ST2 may not overlap the first peripheral structure PD.

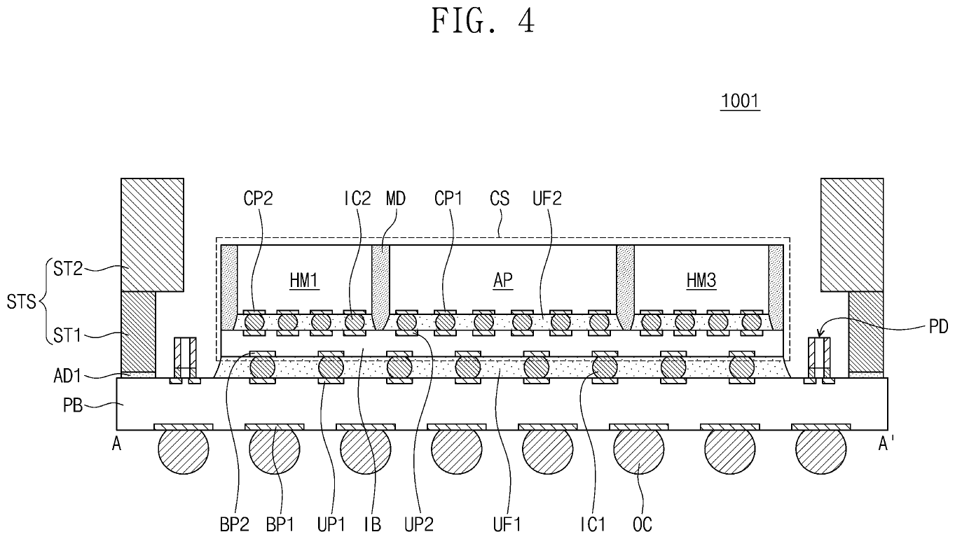

FIG. 4 is a cross-sectional view of FIG. 1 taken along line A-A′ according to embodiments of the present disclosure.

Referring to FIG. 4, in a semiconductor package 1001 according to the present example, in a stiffener structure STS, a second adhesive layer AD2 is not interposed between the first and second stiffeners ST1 and ST2. The first stiffener ST1 and the second stiffener ST2 may be in contact with each other. The first stiffener ST1 and the second stiffener ST2 may be integrally connected. Other structures may be the same/similar to those described with reference to FIGS. 1 to 3. It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting,” “in contact with,” or “contact” another element, there are no intervening elements present at the point of contact.

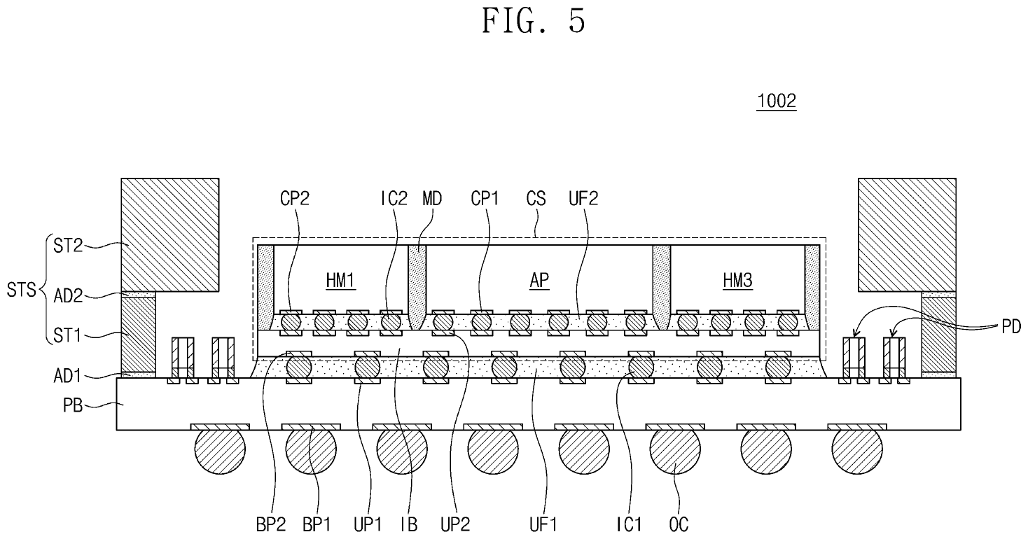

FIG. 5 is a cross-sectional view of a semiconductor package according to embodiments of the present disclosure.

Referring to FIG. 5, in a semiconductor package 1002 according to the present example, first peripheral structures PD may be disposed in a plurality of rows between a stiffener structure STS and a chip structure CS. The first peripheral structures PD may be, for example, passive elements such as capacitors or resistors. First peripheral structures PD may be disposed to surround the chip structure CS. The stiffener structure STS may include a first stiffener ST1 and a second stiffener ST2 sequentially stacked. The second stiffener ST2 may overlap the plurality of first peripheral structures PD. Other structures may be the same/similar to those described with reference to FIGS. 1 to 3.

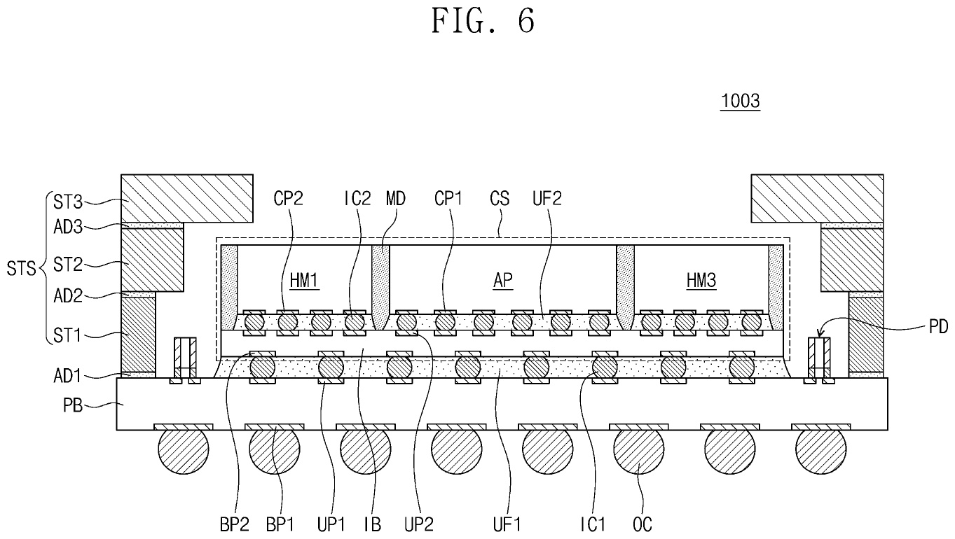

FIG. 6 is a cross-sectional view of a semiconductor package according to embodiments of the present disclosure.

Referring to FIG. 6, in a semiconductor package 1003 according to the present example, a stiffener structure STS includes a first stiffener ST1, a second stiffener ST2, and a third stiffener ST3 sequentially stacked. The first stiffener ST1, the second stiffener ST2, and the third stiffener ST3 may surround the chip structure CS and the first peripheral structures PD. One outer wall of the first stiffener ST1, one outer wall of the second stiffener ST2, and one outer wall of the third stiffener ST3 may all be aligned with each other. A portion of the second stiffener ST2 may protrude to a side of the first stiffener ST1. A portion of the third stiffener ST3 may protrude to a side of the second stiffener ST2. The third stiffener ST3 may overlap the first peripheral structure PD. The third stiffener ST3 may vertically overlap the chip structure CS.

The first stiffener ST1, the second stiffener ST2, and the third stiffener ST3 include different materials. At least one of the first stiffener ST1, the second stiffener ST2, and the third stiffener ST3 may include or may be formed of a metal such as Cu, SUS, Ti, or Al, a ceramic such as silica, titania, or alumina, SiN, or a polymer layer. The first stiffener ST1, the second stiffener ST2, and the third stiffener ST3 have different thermal expansion coefficients. For example, a first coefficient of thermal expansion of the first stiffener ST1 is smaller than a second coefficient of thermal expansion of the second stiffener ST2. The second coefficient of thermal expansion of the second stiffener ST2 is smaller than a third coefficient of thermal expansion of the third stiffener ST3. The first coefficient of thermal expansion of the first stiffener ST1 is similar to/identical to that of the first substrate PB. The first coefficient of thermal expansion of the first stiffener ST1 may be about 9 ppm/° C. to about 13 ppm/° C. The second coefficient of thermal expansion of the second stiffener ST2 may be about 14 ppm/° C. to about 25 ppm/° C. The third coefficient of thermal expansion of the third stiffener ST3 may be about 25.1 ppm/° C. to 30 ppm/° C.

The first stiffener ST1 may include or may be formed of, for example, at least one of stainless use steel (SUS), platinum, MgO, iron, cobalt, and nickel, and the second stiffener ST2 may include or may be formed of, for example, at least one of gold, copper, silicon, and aluminum. The third stiffener ST3 may include or may be formed of, for example, at least one of magnesium, zinc, tin cadmium, and lead. As described above, the stiffener structure STS of the present disclosure includes a plurality of stiffeners ST1, ST2, and ST3 having different thermal expansion coefficients to more effectively suppress and control warpage of the semiconductor package 1003.

The stiffener structure STS further includes a second adhesive layer AD2 interposed between the first and second stiffeners ST1 and ST2. The stiffener structure STS further includes a third adhesive layer AD3 interposed between the second and third stiffeners ST2 and ST3. The second adhesive layer AD2 and the third adhesive layer AD3 may serve to alleviate physical stress. Other structures may be the same/similar to those described with reference to FIGS. 1 to 3.

The structure of the stiffener structure STS of the present disclosure, when the chip structure CS and the first peripheral structure PD are mounted, may maximize a bonding area with the first substrate PB may be effective in suppressing warpage.

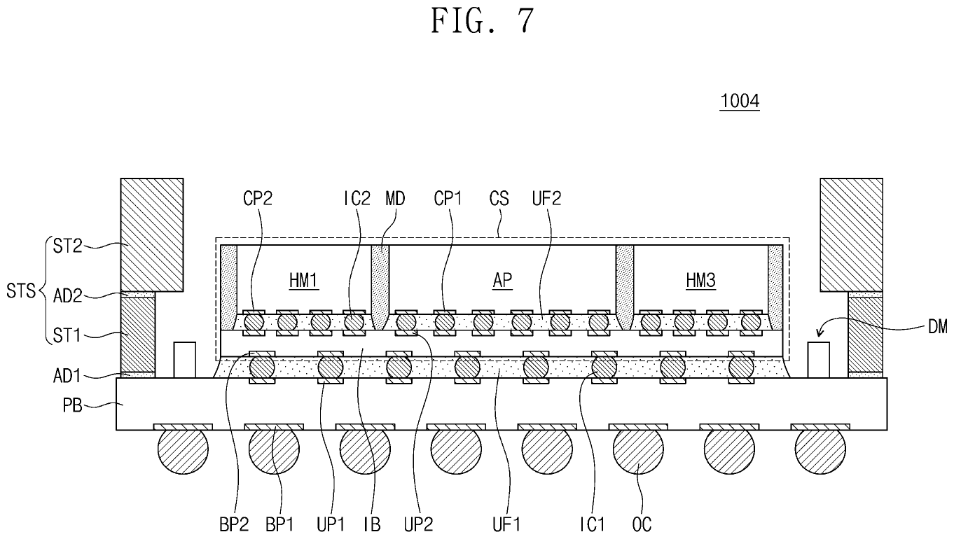

FIG. 7 is a cross-sectional view of a semiconductor package according to embodiments of the present disclosure.

Referring to FIG. 7, in a semiconductor package 1004 according to the present example, a second peripheral structure DM may be disposed between a chip structure CS and stiffener structure STS. The second peripheral structure DM may be a dam preventing a first underfill layer UF1 from flowing to an unwanted region. When viewed in a plan view, the second peripheral structure DM may have a closed curve shape having a cavity, which is an empty space, or a bar shape elongated in one direction. The second peripheral structure DM may surround the chip structure CS. A second stiffener ST2 of the stiffener structure STS may vertically overlap the second peripheral structure DM. Other structures may be the same/similar to those described with reference to FIGS. 1 to 3.

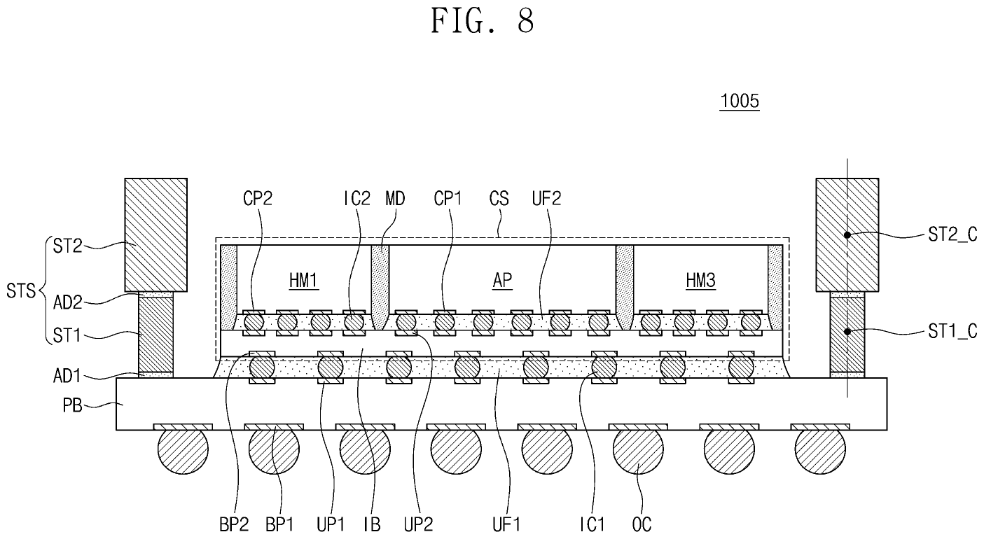

FIG. 8 is a cross-sectional view of a semiconductor package according to embodiments of the present disclosure.

Referring to FIG. 8, a semiconductor package 1005 according to the present example may not include (or exclude) the first peripheral structure PD or the second peripheral structure DM of FIGS. 1 to 7. A stiffener structure STS includes a first stiffener ST1 and a second stiffener ST2 that are sequentially stacked. Outer walls of the first stiffener ST1 may not be aligned with outer walls of the second stiffener ST2, and may be offset from each other. In cross-sections of the first and second stiffeners ST1 and ST2, a center ST1_C of the first stiffener ST1 may be aligned with a center ST2_C of the second stiffener ST2. Other structures may be the same/similar to those described with reference to FIGS. 1 to 3.

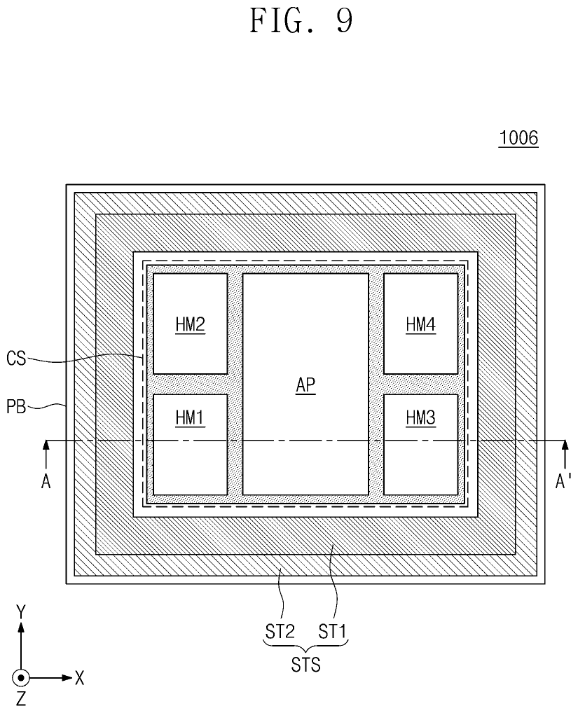

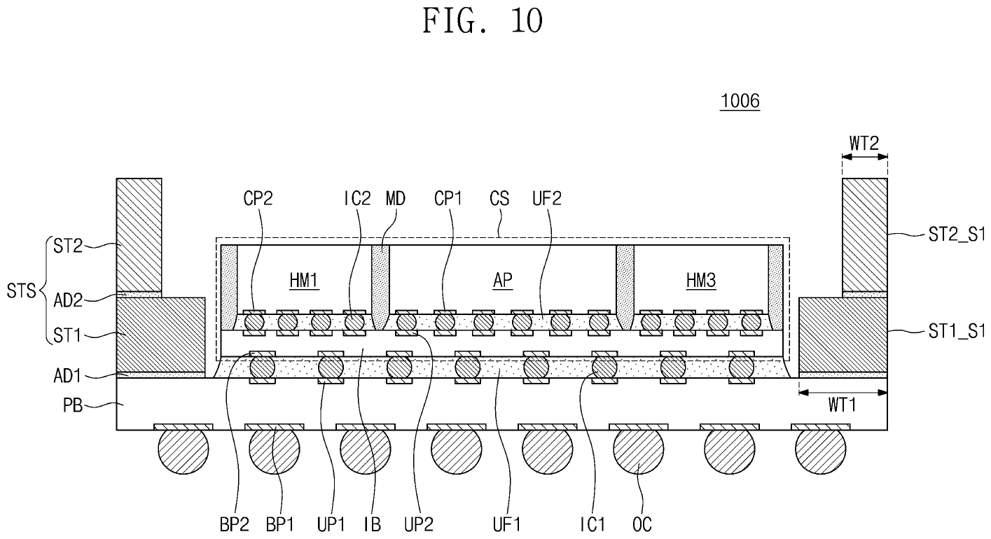

FIG. 9 is a plan view of a semiconductor package according to embodiments of the present disclosure. FIG. 10 is a cross-sectional view of FIG. 9 taken along line A-A′ according to embodiments of the present disclosure.

Referring to FIGS. 9 and 10, a semiconductor package 1006 according to the present example may not include (or exclude) the first peripheral structure PD or the second peripheral structure DM of FIGS. 1 to 7. A stiffener structure STS includes a first stiffener ST1 and a second stiffener ST2 sequentially stacked. One outer wall ST1_S1 of the first stiffener ST1 may be aligned with one outer wall ST2_S1 of the second stiffener ST2. The first stiffener ST1 may have a first width WT1. The second stiffener ST2 may have a second width WT2 smaller than the first width WT1. A portion of the upper surface of the first stiffener ST1 may be exposed without being covered by the second stiffener ST2. Other structures may be the same/similar to those described with reference to FIGS. 1 to 3.

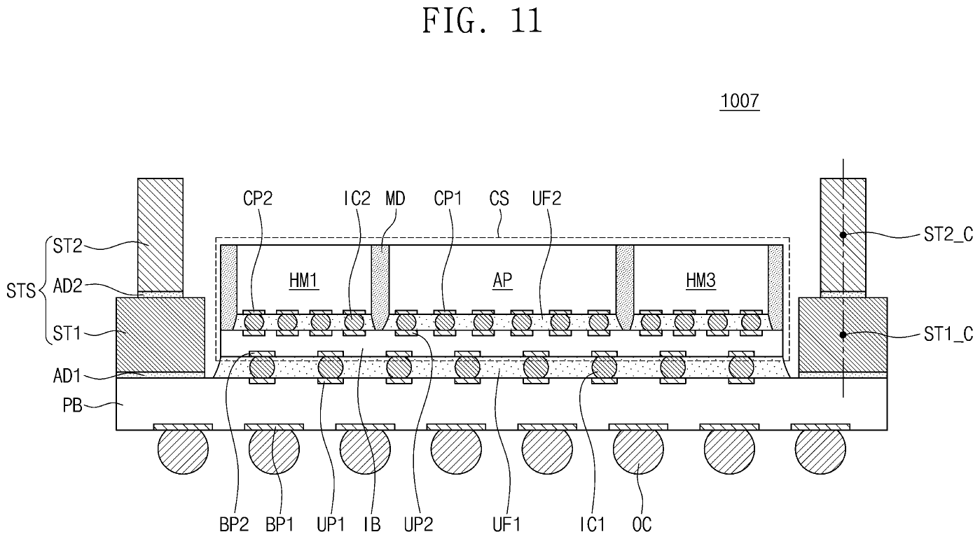

FIG. 11 is a cross-sectional view of a semiconductor package according to embodiments of the present disclosure.

Referring to FIG. 11, in a semiconductor package 1007 according to the present example, a stiffener structure STS includes a first stiffener ST1 and a second stiffener ST2 sequentially stacked. Outer walls of the first stiffener ST1 and outer walls of the second stiffener ST2 may not be aligned, and may be offset from each other. In cross-sections of the first and second stiffeners ST1 and ST2, a center ST1_C of the first stiffener ST1 may be aligned with a center ST2_C of the second stiffener ST2. Other structures may be the same/similar to those described with reference to FIG. 10.

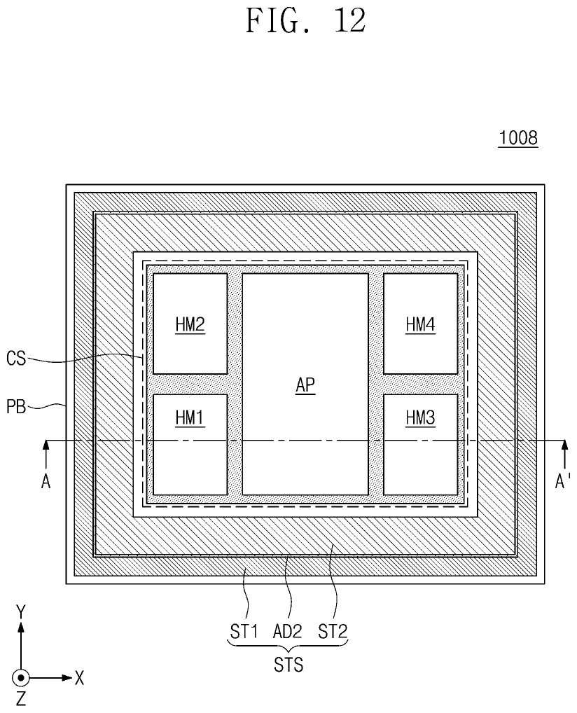

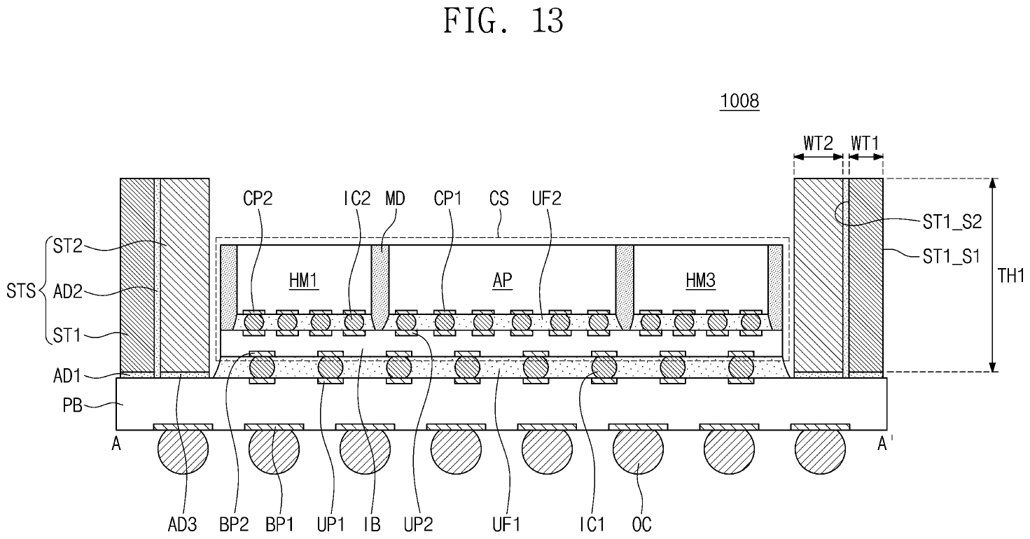

FIG. 12 is a plan view of a semiconductor package according to embodiments of the present disclosure. FIG. 13 is a cross-sectional view of FIG. 12 taken along line A-A′ according to embodiments of the present disclosure.

Referring to FIGS. 12 and 13, a semiconductor package 1008 according to the present example may not include (or exclude) the first peripheral structure PD or the second peripheral structure DM of FIGS. 1 to 7. A stiffener structure STS includes a first stiffener ST1 and a second stiffener ST2 each having a closed curve shape having an empty space inside when viewed in a plan view. The first stiffener ST1 and the second stiffener ST2 surround the chip structure CS, respectively. The first stiffener ST1 has an outer wall ST1_S1 and an inner wall ST1_S2. The second stiffener ST2 may be attached to the inner wall ST1_S2 of the first stiffener ST1 by a second adhesive layer AD2. That is, the second adhesive layer AD2 is interposed between the first and second stiffeners ST1 and ST2. The first stiffener ST1 surrounds the second stiffener ST2.

The first stiffener ST1 is attached to an upper surface of a first substrate PB by a first adhesive layer AD1. The second stiffener ST2 is attached to the upper surface of the first substrate PB by a third adhesive layer AD3. Each of the first and second stiffeners ST1 and ST2 may have a first thickness TH1. Upper surfaces of the first stiffener ST1 and the second stiffener ST2 may be coplanar with each other. The first stiffener ST1 may have a first width WT1. The second stiffener ST2 may have a second width WT2 different from the first width WT1. For example, the second width WT2 may be greater than the first width WT1. Other structures may be the same/similar to those described with reference to FIGS. 1 to 3.

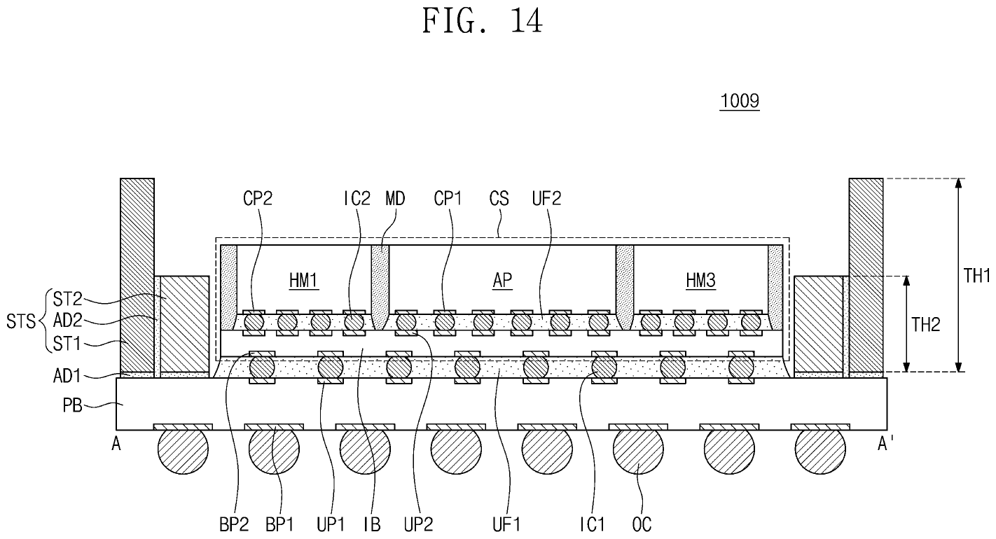

FIG. 14 is a cross-sectional view of FIG. 12 taken along line A-A′ according to embodiments of the present disclosure.

Referring to FIG. 14, a semiconductor package 1009 according to the present example may not include (or exclude) the first peripheral structure PD or the second peripheral structure DM of FIGS. 1 to 7. A stiffener structure STS includes a first stiffener ST1 and a second stiffener ST2 each having a closed curve shape having an empty space inside when viewed in a plan view. The first stiffener ST1 and the second stiffener ST2 surround the chip structure CS, respectively. The first stiffener ST1 surrounds the second stiffener ST2. The first stiffener ST1 may have a first thickness TH1. The second stiffener ST2 may have a second thickness TH2 smaller than the first thickness TH1. An upper side surface of the first stiffener ST1 may be exposed without being covered by the second stiffener ST2. Other structures may be the same/similar to those described with reference to FIGS. 12 and 13.

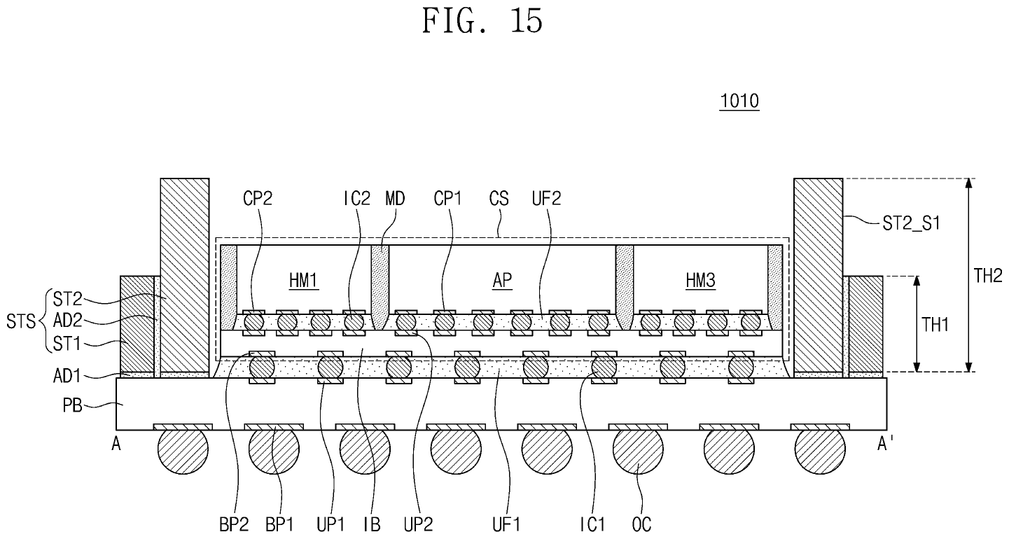

FIG. 15 is a cross-sectional view of FIG. 12 taken along line A-A′ according to embodiments of the present disclosure.

Referring to FIG. 15, a semiconductor package 1010 according to the present example may not include (or exclude) the first peripheral structure PD or the second peripheral structure DM of FIGS. 1 to 7. A stiffener structure STS includes a first stiffener ST1 and a second stiffener ST2 each having a closed curve shape having an empty space inside when viewed in a plan view. The first stiffener ST1 and the second stiffener ST2 surround the chip structure CS, respectively. The first stiffener ST1 surrounds the second stiffener ST2. The first stiffener ST1 may have a first thickness TH1. The second stiffener ST2 may have a second thickness TH2 greater than the first thickness TH1. An upper portion of the outer wall ST2_S1 of the second stiffener ST2 may be exposed without being covered by the first stiffener ST1. Other structures may be the same/similar to those described with reference to FIGS. 12 and 13.

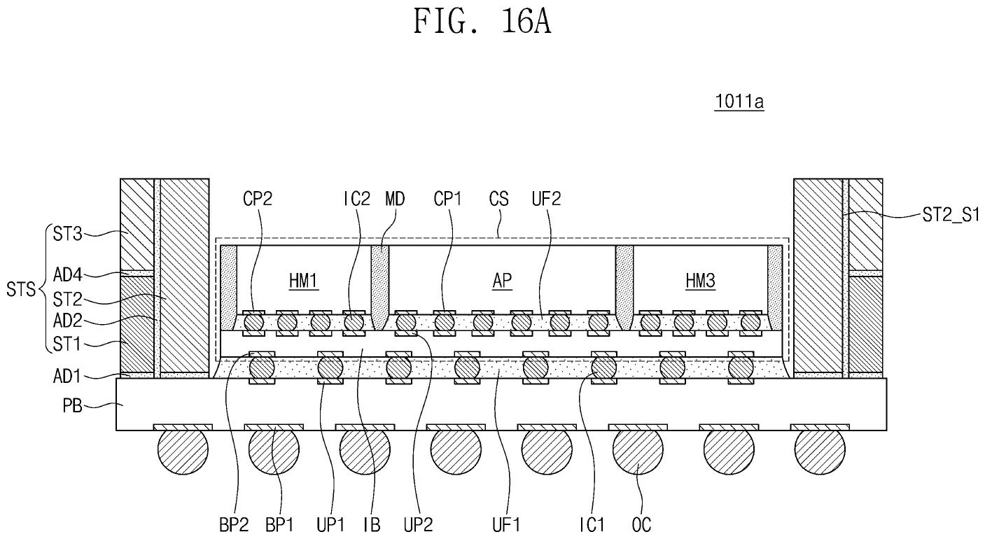

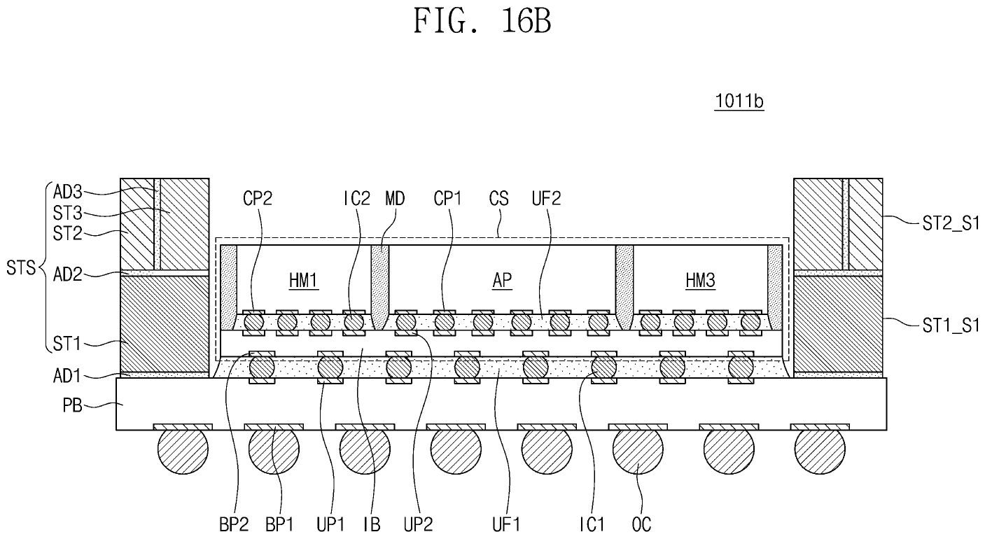

FIG. 16A is a cross-sectional view of a semiconductor package according to embodiments of the present disclosure.

Referring to FIG. 16A, a semiconductor package 1011a according to the present example may not include (or exclude) the first peripheral structure PD or the second peripheral structure DM of FIGS. 1 to 7. A stiffener structure STS includes first to third stiffeners ST1, ST2, and ST3. Structures of the first and second stiffeners ST1 and ST2 are the same as those disclosed in FIG. 15. The third stiffener ST3 may be disposed on the first stiffener ST1 and may surround the second stiffener ST2. The third stiffener ST3 may be attached to an upper portion of an outer wall ST2_S1 of the second stiffener ST2 by a second adhesive layer AD2. A fourth adhesive layer AD4 may be interposed between the third stiffener ST3 and the first stiffener ST1. Upper surfaces of the third stiffener ST3 and the second stiffener ST2 may be coplanar with each other. Other structures may be the same/similar to those described with reference to FIGS. 12 and 13.

FIG. 16B is a cross-sectional view of a semiconductor package according to embodiments of the present disclosure.

Referring to FIG. 16B, a semiconductor package 1011b according to the present example may not include (exclude) the first peripheral structure PD or the second peripheral structure DM of FIGS. 1 to 7. A stiffener structure STS includes first to third stiffeners ST1, ST2, and ST3. Each of the first to third stiffeners ST1, ST2, and ST3 may have a closed curve shape having a cavity, which is an empty space, inside when viewed in a plan view. Structures of the first and second stiffeners ST1 and ST2 are the same as those disclosed in FIG. 10. The second stiffener ST2 and the third stiffener ST3 are disposed on the first stiffener ST1. The second stiffener ST2 and the third stiffener ST3 are attached to an upper surface of the first stiffener ST1 by a second adhesive layer AD2. A third adhesive layer AD3 is interposed between the second and third stiffeners ST2 and ST3. Upper surfaces of the second and third stiffeners ST2 and ST3 may be coplanar with each other. A width of the first stiffener ST1 may be substantially equal to the sum of widths of the second and third stiffeners ST2 and ST3. Other structures may be the same/similar to those described with reference to FIG. 10.

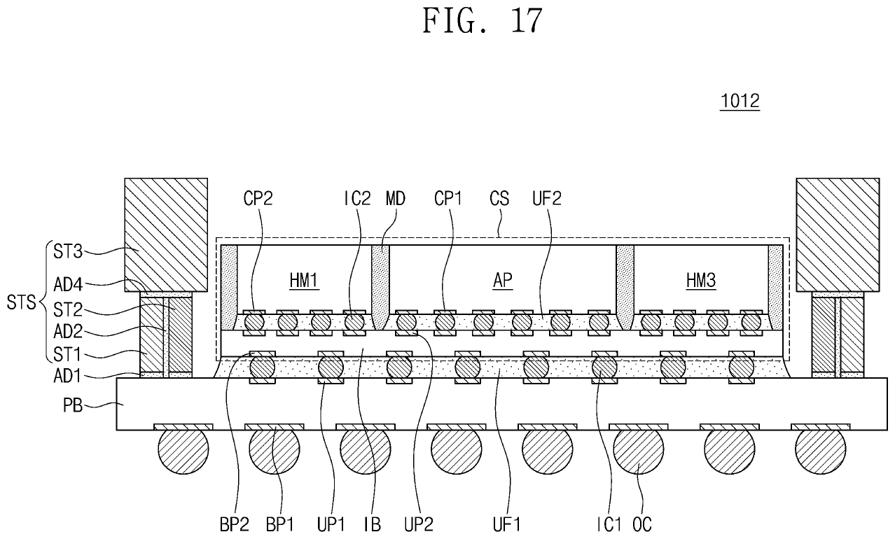

FIG. 17 is a cross-sectional view of a semiconductor package according to embodiments of the present disclosure.

Referring to FIG. 17, a semiconductor package 1012 according to the present example may not include (or exclude) the first peripheral structure PD or the second peripheral structure DM of FIGS. 1 to 7. A stiffener structure STS includes first to third stiffeners ST1, ST2, and ST3. The second stiffener ST2 is attached to an inner wall of the first stiffener ST1 by a second adhesive layer AD2. The first and second stiffeners ST1 and ST2 may have the same thickness, and upper surfaces thereof may be coplanar with each other. The third stiffener ST3 may be disposed on the first stiffener ST1 and the second stiffener ST2. The third stiffener ST3 may be attached to the first stiffener ST1 and the second stiffener ST2 by a fourth adhesive layer AD4. A width of the third stiffener ST3 may be greater than the sum of widths of the first stiffener ST1 and the second stiffener ST2. Sidewalls of the third stiffener ST3 are not aligned with the sidewalls of the first and second stiffeners ST1 and ST2. A center of a lower structure including the first stiffener ST1 and the second stiffener ST2 may be aligned with a center of the third stiffener ST3. Other structures may be the same/similar to those described with reference to FIGS. 1 to 3.

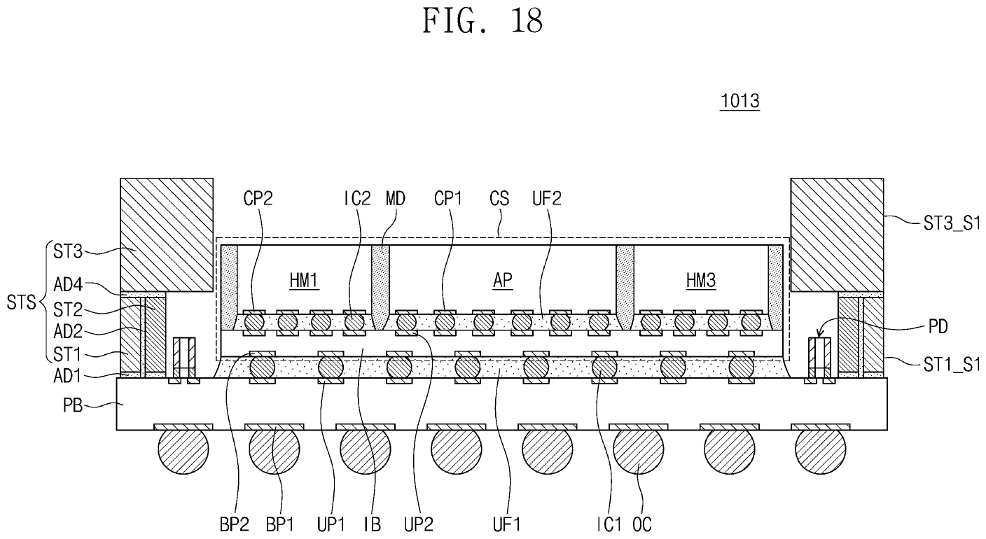

FIG. 18 is a cross-sectional view of a semiconductor package according to embodiments of the present disclosure.

Referring to FIG. 18, a semiconductor package 1013 according to the present example includes a first peripheral structure PD disposed between a stiffener structure STS and a chip structure CS. The stiffener structure STS includes first to third stiffeners ST1, ST2, and ST3. The second stiffener ST2 is attached to an inner wall of the first stiffener ST1 by a second adhesive layer AD2. The first and second stiffeners ST1 and ST2 may have the same thickness, and upper surfaces thereof may be coplanar with each other. The third stiffener ST3 may be disposed on the first stiffener ST1 and the second stiffener ST2. An outer wall ST3_S1 of the third stiffener ST3 may be aligned with an outer wall ST1_S1 of the first stiffener ST1. A width of the third stiffener ST3 may be greater than the sum of widths of the first stiffener ST1 and the second stiffener ST2. A portion of the third stiffener ST3 vertically overlaps the first peripheral structure PD. Other structures may be the same/similar to those described with reference to FIGS. 1 to 3 and FIG. 17.

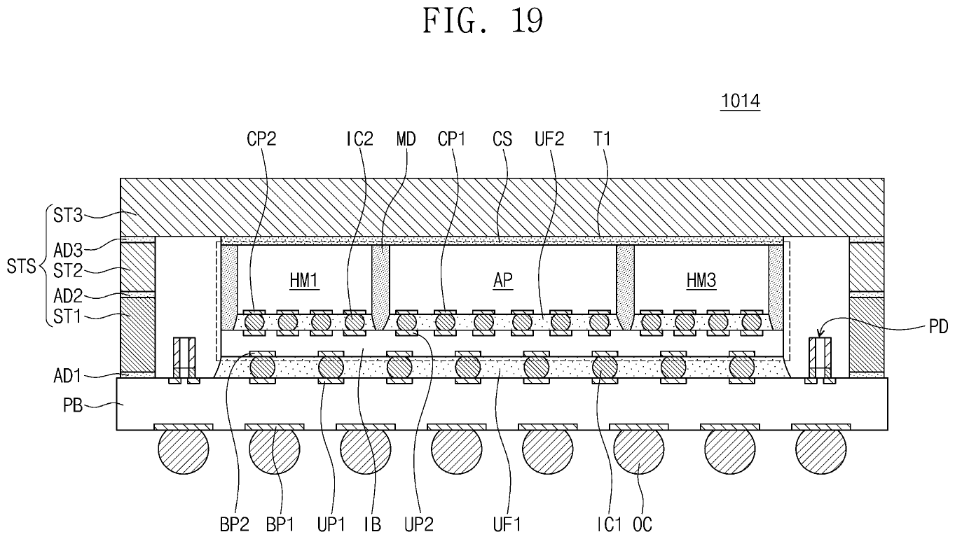

FIG. 19 is a cross-sectional view of a semiconductor package according to embodiments of the present disclosure.

Referring to FIG. 19, a semiconductor package 1014 according to the present example includes a first peripheral structure PD disposed between a stiffener structure STS and a chip structure CS. The stiffener structure STS includes a first stiffener ST1, a second stiffener ST2, and a third stiffener ST3 that are sequentially stacked. The first stiffener ST1 is attached to the upper surface of the first substrate PB by the first adhesive layer AD1. The second stiffener ST2 is attached to the first stiffener ST1 by the second adhesive layer AD2. The third stiffener ST3 is attached to second stiffener ST2 by the third adhesive layer AD3. The first stiffener ST1 and the second stiffener ST2 may surround the chip structure CS and the first peripheral structures PD, respectively. The third stiffener ST3 may completely cover the chip structure CS. The first stiffener ST1 and the second stiffener ST2 have the same width, and sidewalls thereof may be aligned with each other. The third stiffener ST3 may also be referred to as a ‘heat sink’, ‘heat spread’ or ‘heat dissipation member’. A thermal conductivity of the third stiffener ST3 may be greater than those of the first and second stiffeners ST1 and ST2. A coefficient of thermal expansion of the third stiffener ST3 may be greater than those of the first and second stiffeners ST1 and ST2. A thermal boundary material layer TI may be interposed between the third stiffener ST3 and the chip structure CS. The thermal boundary material layer TI may include a thermally curable resin layer. The thermal boundary material layer TI may further include filler particles dispersed in the thermally curable resin layer. The filler particles may include or may be formed of at least one of silica, alumina, zinc oxide, and nitrogen boride. In the present disclosure, at least one of the first to third adhesive layers AD1 to AD3 may include the same material as the thermal boundary material layer TI. Other structures may be the same/similar to those of FIG. 6.

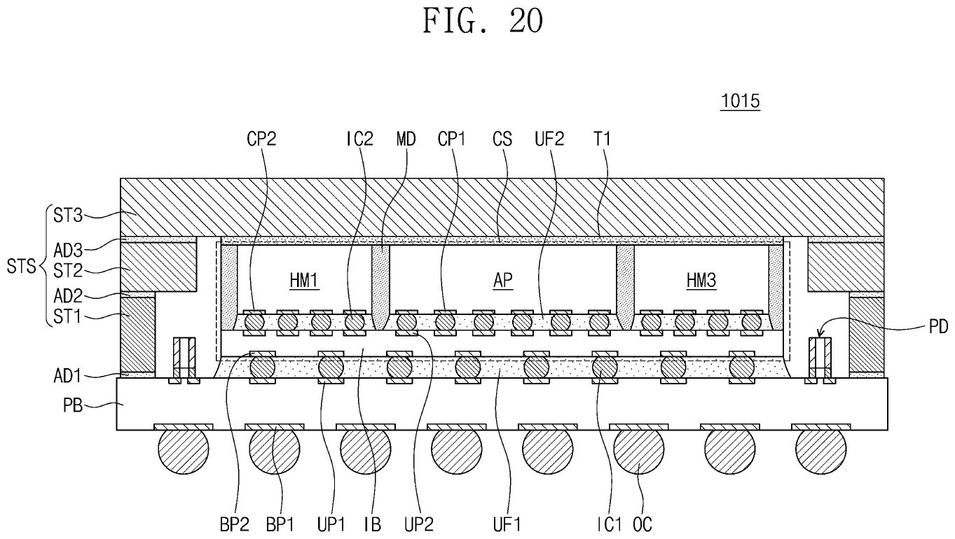

FIG. 20 is a cross-sectional view of a semiconductor package according to embodiments of the present disclosure.

Referring to FIG. 20, a semiconductor package 1015 according to the present example includes a first peripheral structure PD disposed between a stiffener structure STS and a chip structure CS. The stiffener structure STS includes a first stiffener ST1, a second stiffener ST2, and a third stiffener ST3 that are sequentially stacked. The first stiffener ST1 and the second stiffener ST2 may surround the chip structure CS and first peripheral structures PD, respectively. The third stiffener ST3 may completely cover the chip structure CS. An outer wall of the first stiffener ST1 and an outer wall of the second stiffener ST2 may be aligned with each other. A width of the second stiffener ST2 may be greater than that of the first stiffener ST1. A portion of the second stiffener ST2 may protrude from a side of the first stiffener ST1 and vertically overlap the first peripheral structure PD. Other structures may be the same/similar to those of FIG. 19.

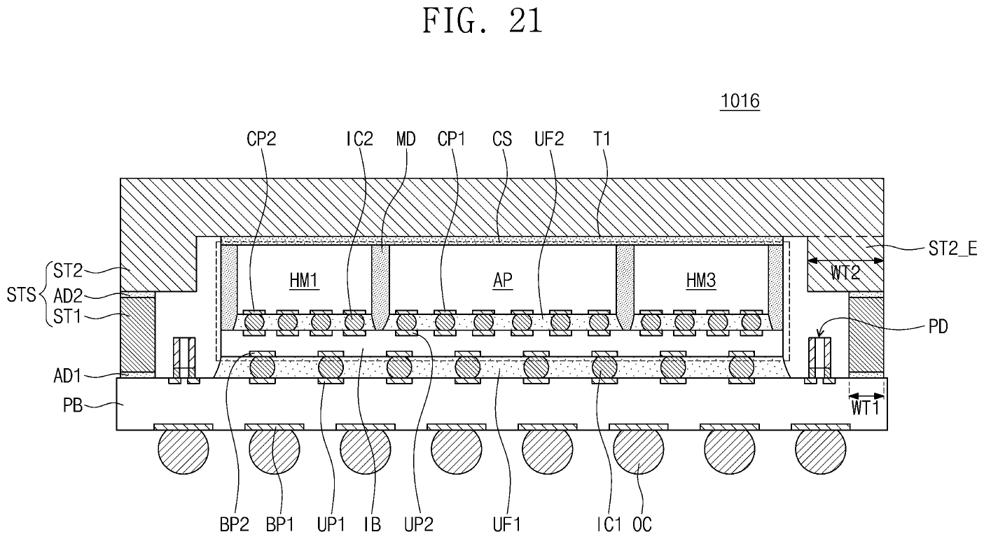

FIG. 21 is a cross-sectional view of a semiconductor package according to embodiments of the present disclosure.

Referring to FIG. 21, a semiconductor package 1016 according to the present example includes a first peripheral structure PD disposed between a stiffener structure STS and a chip structure CS. The stiffener structure STS includes a first stiffener ST1 and a second stiffener ST2 that are sequentially stacked. The first stiffener ST1 may surround the chip structure CS and a first peripheral structures PD. The second stiffener ST2 may completely cover the chip structure CS. The second stiffener ST2 may also be referred to as a ‘heat sink’, ‘heat spread’ or ‘heat dissipation member’. A thermal conductivity of the second stiffener ST2 may be greater than that of the first stiffener ST1. A coefficient of thermal expansion of the second stiffener ST2 may be greater than that of the first stiffener ST1. An edge portion ST2_E of the second stiffener ST2 may protrude downward and may be adjacent to the first stiffener ST1 (e.g., an upper surface of the first stiffener ST1). The first stiffener ST1 may have a first width WT1. An edge portion ST2_E of the second stiffener ST2, disposed on the first stiffener ST1, may have a second width WT2 greater than the first width WT1. A lower surface of the edge portion ST2_E of the second stiffener ST2 may be partially exposed. For example, a portion of the edge portion ST2_E of the second stiffener ST2 may vertically overlap the first peripheral structure PD. A second adhesive layer AD2 may be interposed between the first and second stiffeners ST1 and ST2. However, in accordance with other aspects of the inventive concept, the first stiffener ST1 may be in contact with the second stiffener ST2 without the second adhesive layer AD2 interposed between. The first stiffener ST1 and the second stiffener ST2 may be integrally formed. Other structures may be the same/similar to those of FIG. 20.

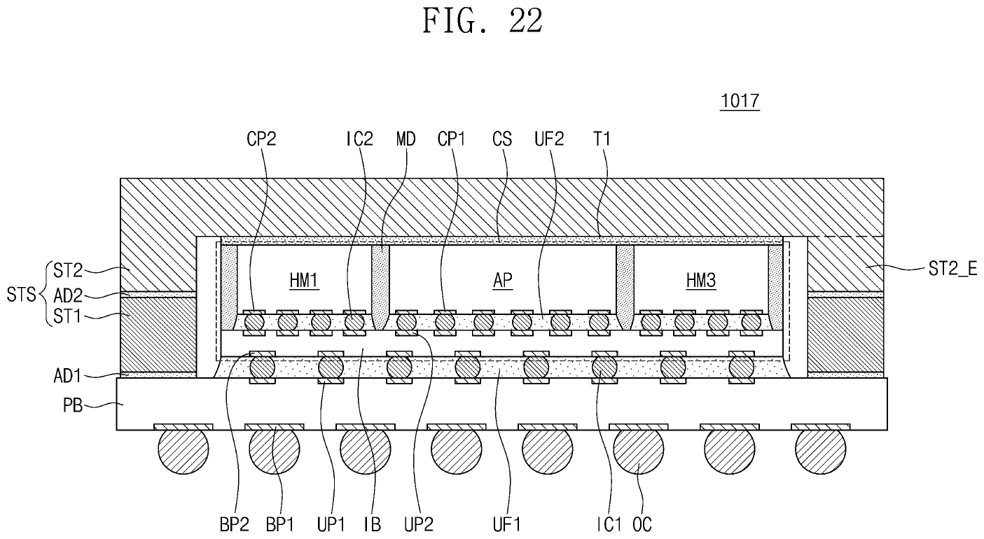

FIG. 22 is a cross-sectional view of a semiconductor package according to embodiments of the present disclosure.

Referring to FIG. 22, a semiconductor package 1017 according to the present example may not include (or exclude) the first peripheral structure PD or the second peripheral structure DM of FIGS. 1 to 7. A stiffener structure STS includes a first stiffener ST1 and a second stiffener ST2 that are sequentially stacked. The first stiffener ST1 may surround a chip structure CS. The second stiffener ST2 may completely cover the chip structure CS. An edge portion ST2_E of the second stiffener ST2 may have the same width as the first stiffener ST1. Other structures may be the same/similar to those of FIG. 21.

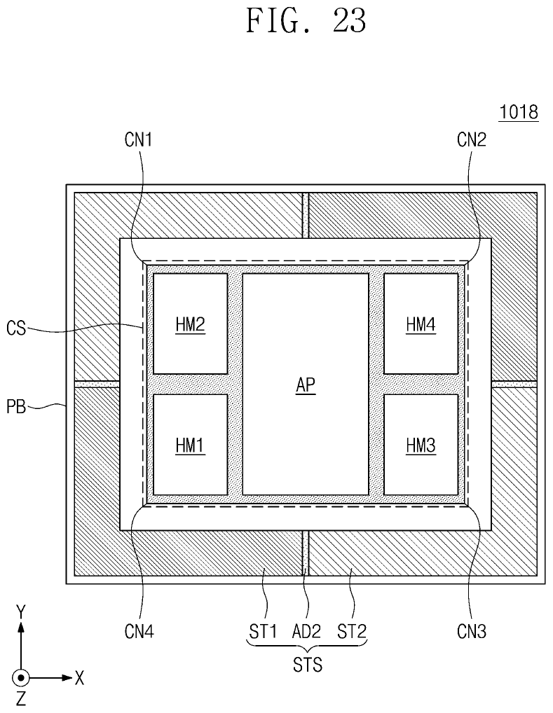

FIG. 23 is a plan view of a semiconductor package according to embodiments of the present disclosure.

Referring to FIG. 23, in a semiconductor package 1018 according to the present example, a stiffener structure STS may surround a chip structure CS. The stiffener structure STS includes first stiffeners ST1 and second stiffeners ST2. The first stiffener ST1 and the second stiffener ST2 may each have an ‘L’ shape when viewed in a plan view. The chip structure CS includes first to fourth corners CN1 to CN4 disposed in a clockwise direction. The second stiffeners ST2 may be adjacent to the first and third corners CN1 and CN3 and may cover the first and third corners CN1 and CN3. The first stiffeners ST1 may be adjacent to the second and fourth corners CN2 and CN4 and may cover the second and fourth corners CN2 and CN4. A second adhesive layer AD2 may be interposed between the first stiffeners ST1 and the second stiffeners ST2. The first stiffeners ST1 may have a different coefficient of thermal expansion from that of the second stiffeners ST2. Other structures may be the same/similar to those described with reference to FIGS. 9 and 10.

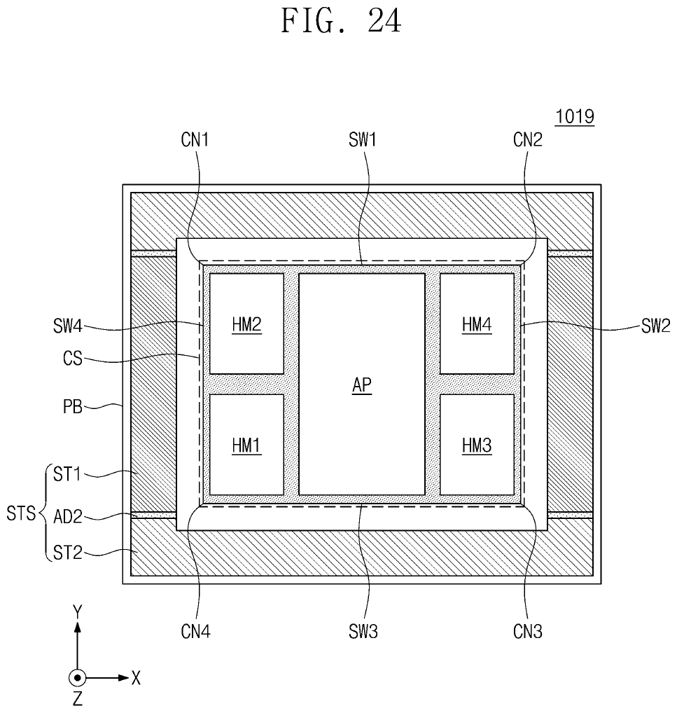

FIG. 24 is a plan view of a semiconductor package according to embodiments of the present disclosure.

Referring to FIG. 24, in a semiconductor package 1019 according to the present example, a stiffener structure STS may surround a chip structure CS. The stiffener structure STS includes first stiffeners ST1 and second stiffeners ST2. When viewed in a plan view, the first stiffener ST1 may have an ‘I’ shape. When viewed in a plan view, the second stiffener ST2 may have a ‘U’ shape. The chip structure CS includes first to fourth corners CN1 to CN4 and first to fourth sidewalls SW1 to SW4 disposed in a clockwise direction. The second stiffeners ST2 may be adjacent to the first to fourth corners CN1 to CN4 and cover the first to fourth corners CN1 to CN4. The second stiffeners ST2 may be adjacent to the first and third sidewalls SW1 and SW3 of the chip structure CS. The first stiffeners ST1 may be adjacent to the second and fourth sidewalls SW2 and SW4 of the chip structure CS. A second adhesive layer AD2 may be interposed between the first stiffeners ST1 and the second stiffeners ST2. Other structures may be the same/similar to those described with reference to FIG. 23.

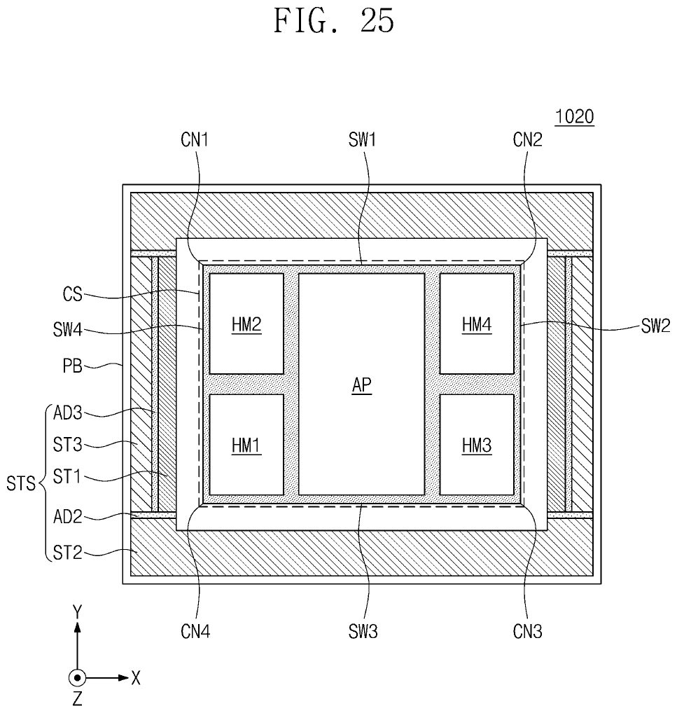

FIG. 25 is a plan view of a semiconductor package according to embodiments of the present disclosure.

Referring to FIG. 25, in a semiconductor package 1020 according to the present example, a stiffener structure STS may surround a chip structure CS. The stiffener structure STS includes first to third stiffeners ST1, ST2, and ST3. When viewed in a plan view, the first and third stiffeners ST1 and ST3 may have an ‘I’ shape. When viewed in a plan view, the second stiffeners ST2 may have a ‘U’ shape. The chip structure CS includes first to fourth corners CN1 to CN4 and first to fourth sidewalls SW1 to SW4 disposed in a clockwise direction. The second stiffeners ST2 may be adjacent to the first to fourth corners CN1 to CN4 and cover the first to fourth corners CN1 to CN4. The second stiffeners ST2 may be adjacent to the first and third sidewalls SW1 and SW3 of the chip structure CS. The first and third stiffeners ST1 and ST3 may be adjacent to the second and fourth sidewalls SW2 and SW4 of the chip structure CS. The third stiffener ST3 may be attached to an inner wall of the first stiffener ST1 by a third adhesive layer AD3. Other structures may be the same/similar to those described with reference to FIG. 24.

In the semiconductor package according to the present disclosure, the structure of the stiffener structure may be varied, the stiffener structure may include the plurality of stiffeners having the different materials, and thus the warpage of the semiconductor package may be effectively suppressed or controlled in the minimum area.

While embodiments are described above, a person skilled in the art may understand that many modifications and variations are made without departing from the spirit and scope of the present disclosure defined in the following claims. Accordingly, the example embodiments of the present disclosure should be considered in all respects as illustrative and not restrictive, with the spirit and scope of the present disclosure being indicated by the appended claims. Aspects of the embodiments of FIGS. 1 through 25 can be combined with each other.

What is claimed is:

1. A semiconductor package comprising:
a package substrate;
a chip structure on the package substrate;
a peripheral structure disposed on the package substrate and around the chip structure; and
a stiffener structure disposed at an edge of the package substrate and surrounding the peripheral structure and the chip structure,
wherein the stiffener structure includes a first stiffener and a second stiffener that are sequentially stacked,
wherein the second stiffener includes a material different from a material of the first stiffener, and
wherein the second stiffener has a second width wider than a first width of the first stiffener and vertically overlaps the peripheral structure.

2. The semiconductor package of claim 1, wherein the peripheral structure is at least one of a capacitor, a resistor, and a dam.

3. The semiconductor package of claim 1, wherein a coefficient of thermal expansion of the first stiffener is smaller than a coefficient of thermal expansion of the second stiffener.

4. The semiconductor package of claim 1, wherein the stiffener structure further includes a third stiffener stacked on the second stiffener,
wherein the third stiffener includes a material different from a material of at least one of the first stiffener and the second stiffener, and
wherein the third stiffener overlaps the chip structure.

5. The semiconductor package of claim 1, wherein a first height of an upper surface of the stiffener structure is higher than a second height of an upper surface of the chip structure from an upper surface of the package substrate, and
wherein the first height is 1.1 to 3 times the second height.

6. The semiconductor package of claim 1, wherein the stiffener structure further includes an adhesive layer interposed between the first stiffener and the second stiffener.

7. The semiconductor package of claim 1, wherein one sidewall of the first stiffener is aligned with one sidewall of the second stiffener, or
wherein a center of the first stiffener vertically overlaps a center of the second stiffener.

8. The semiconductor package of claim 1, wherein the stiffener structure further includes a third stiffener adjacent to a side surface of the second stiffener or a side surface of the first stiffener, the third stiffener surrounding both the chip structure and the peripheral structure, and
wherein the third stiffener includes a material different from a material of at least one of the first stiffener and the second stiffener.

9. The semiconductor package of claim 1, wherein the first stiffener surrounds both the chip structure and the peripheral structure when viewed in a plan view, and
wherein the second stiffener extends to cover the chip structure.

10. The semiconductor package of claim 1, further comprising a thermal boundary material layer interposed between the second stiffener and the chip structure.

11. A semiconductor package comprising:
a package substrate;
an interposer substrate on the package substrate;
an application-specific semiconductor chip disposed on a center of the interposer substrate;
first and second memory chips disposed on one side of the application-specific semiconductor chip;
third and fourth memory chips disposed on another side of the application-specific semiconductor chip;
a mold layer covering the application-specific semiconductor chip, the first to fourth memory chips, and the interposer substrate; and
a stiffener structure disposed at an edge of the package substrate and surrounding the interposer substrate,
wherein the stiffener structure includes a first stiffener and a second stiffener that are sequentially stacked,
wherein the second stiffener includes a material different from a material of the first stiffener,
wherein the second stiffener has a second width wider than a first width of the first stiffener, and
wherein a coefficient of thermal expansion of the first stiffener is smaller than a coefficient of thermal expansion of the second stiffener.

12. The semiconductor package of claim 11, further comprising passive elements disposed on the package substrate and between the interposer substrate and the first stiffener,
wherein the second stiffener vertically overlaps the passive elements, and
wherein the passive elements are at least one of a capacitor and a resistor.

13. The semiconductor package of claim 11, wherein the stiffener structure further includes a third stiffener stacked on the second stiffener,
wherein the third stiffener includes a material different from a material of at least one of the first stiffener and the second stiffener, and
wherein the third stiffener overlaps the application-specific semiconductor chip, the first to fourth memory chips, and the interposer substrate.

14. The semiconductor package of claim 11, wherein a first height of an upper surface of the stiffener structure is higher than a second height of an upper surface of the application-specific semiconductor chip, and
wherein the first height is 1.1 to 3 times the second height.

15. The semiconductor package of claim 11, wherein the stiffener structure further includes an adhesive layer interposed between the first stiffener and the second stiffener.

16. The semiconductor package of claim 11, wherein one sidewall of the first stiffener is aligned with one sidewall of the second stiffener, or
wherein a center of the first stiffener vertically overlaps a center of the second stiffener.

17. The semiconductor package of claim 11, wherein the stiffener structure further includes a third stiffener adjacent to a side surface of the second stiffener or a side surface of the first stiffener, the stiffener structure surrounding the interposer substrate, and
wherein the third stiffener includes a material different from a material of at least one of the first stiffener and the second stiffener.

18. A semiconductor package comprising:
a package substrate;
a chip structure on the package substrate; and
a stiffener structure disposed at an edge of the package substrate and surrounding the chip structure,
wherein the stiffener structure includes a first stiffener and a second stiffener formed of different materials, and
wherein the first stiffener and the second stiffener surround the chip structure when viewed in a plan view, and the second stiffener is adjacent to an inner wall of the first stiffener.

19. The semiconductor package of claim 18, wherein a height of an upper surface of the first stiffener is different from a height of an upper surface of the second stiffener.

20. The semiconductor package of claim 18, wherein the stiffener structure further comprises a third stiffener disposed on at least one of the first stiffener and the second stiffener, and
wherein the third stiffener includes a material different from a material of at least one of the first stiffener and the second stiffener.
